(19) United States
(12) Patent Application Publication
(10) Pub. No.: US 2015/0373857 A1
(43) Pub. Date: Dec. 24, 2015

(54) DISPLAY APPARATUS AND TELEVISION RECEIVER

(71) Applicant: SHARP KABUSHIKI KAISHA, Osaka-shi, Osaka (JP)

(72) Inventor: Hideyuki CHIKAZAWA, Osaka-shi (JP)

(73) Assignee: SHARP KABUSHIKI KAISHA, Osaka-shi, Osaka (JP)

(21) Appl. No.: 14/410,152

(22) PCT Filed: Jun. 20, 2013
(86) PCT No.: PCT/JP2013/066905

§ 371 Date: Dec. 22, 2014

(30) Foreign Application Priority Data
Jun. 25, 2012 (JP) 2012-142057

(51) Int. Cl. H05K 5/00; H05K 5/03; H04N 5/455

(52) U.S. Cl. CPC H05K 5/0017; H04N 5/455; H05K 5/03

(57) ABSTRACT

In a display apparatus included in a television receiver, a cover covers peripheral edge part of a display panel for displaying an image from an outside of a backlight chassis that surrounds a peripheral surface of a display panel. The cover is configured by a plurality of cover sections, each of which covers a portion of the peripheral edge part of the display panel. On a cover section which is one of the plurality of cover sections, a protrusion which protrudes from an upper wall covering the peripheral surface of the display panel is provided. In an upper wall of the backlight chassis covering the peripheral surface of the display panel, an insertion hole is provided, and the protrusion is fixed with inserted into the insertion hole.

This application is the national phase under 35 U.S.C. §371 of PCT International Application No. PCT/JP2013/066905 which has an International filing date of Jun. 20, 2013 and designated the United States of America.

### FIELD

The present invention relates to a display apparatus for displaying an image and a television receiver.

### BACKGROUND

Recently, the size of a liquid crystal display apparatus including a liquid crystal display panel as an image display unit is becoming larger. The liquid crystal display panel of the liquid crystal display apparatus is formed to have a rectangular plate shape, and has a display surface for displaying an image, formed on one surface (front surface) thereof. The liquid crystal display apparatus includes a light source unit disposed at a rear side thereof and irradiating light to a rear surface of the liquid crystal display panel, and the light source unit is supported by a backlight chassis.

The liquid crystal display panel has a rear surface covered by cabinet from a rear side of the light source unit and the backlight chassis. The liquid crystal display panel has a peripheral edge part of the display surface and a peripheral surface, the peripheral edge part and the peripheral surface covered by a cover. The cover is an injection molded piece made of a resin.

In a large liquid crystal display apparatus, the liquid crystal panel has large vertical and horizontal dimensions. When the cover is manufactured by injection molding, a large mold is required, and therefore there is a problem that the display apparatus is manufactured at high cost.

Japanese Patent Application Laid-Open No. 2011-133546 discloses a liquid crystal module in which the liquid crystal display panel has side portions covered by four bezel constituting frame members.

It is considered that the above-described cover may be configured by four cover sections which cover the peripheral edge part on respective sides of the liquid crystal display panel, as the bezel constituting frame members described in Japanese Patent Application Laid-Open No. 2011-133546. In this case, the four cover sections can be individually manufactured by extrusion molding, and a large size mold is unnecessary in the extrusion molding. Therefore, it is possible to manufacture the apparatus at low cost.

Meanwhile, the liquid crystal display apparatus is required to be thinner and lighter. In order to meet the requirements of being thinner and lighter, it is considered that the backlight chassis is used as an exterior body without using the cabinet. In the liquid crystal display apparatus using the backlight chassis as the exterior body, the backlight chassis also serves as a role of a cabinet.

From the above description, as a thin, light and inexpensive liquid crystal display apparatus, a liquid crystal display apparatus, in which the backlight chassis is configured as an exterior body, and a cover that covers the peripheral edge part of the liquid crystal display panel is configured by four cover sections, may be considered.

FIG. 1 is a longitudinal cross-sectional view of a liquid crystal display apparatus illustrated as an example. FIG. 1 illustrates an upper portion of a liquid crystal display apparatus 9. The liquid crystal display apparatus 9 includes a backlight chassis 90. The backlight chassis 90 has a rectangular plate-like bottom plate 90a, and side walls 90b, 90b, 90b and 90b (only one is illustrated in FIG. 1) which vertically extend in the same direction from respective sides of the bottom plate 90a. The backlight chassis 90 is formed to have a box-like shape with one surface opened, as a whole.

A reflection sheet 91, a light guide plate 92, an optical sheet group 93, and a liquid crystal display panel 94 are laminated in order from a rear side (right side in FIG. 1) to a front side on the bottom plate 90a of the backlight chassis 90. Light emitted from a light source (not illustrated) disposed so as to face one end surface of the light guide plate 92 enters into the light guide plate 92.

The light which has entered into the light guide plate 92 propagates through the light guide plate 92 by repeating reflection on the front and rear surfaces. The light is totally reflected on the rear surface of the light guide plate 92 by an operation of the reflection sheet 91 disposed on the rear side of the light guide plate 92. The light is partially reflected on the front surface of the light guide plate 92, and thus a part of the light propagating through the light guide plate 92 is emitted to an outside. The above-described reflection of the light which has entered into the light guide plate 92 is repeatedly performed on the front and rear surface so that the light is uniformly emitted from the front surface of the light guide plate 92.

The light emitted from the front surface of the light guide plate 92 passes through the optical sheet group 93 including, for example, a view expansion sheet and an anti-reflection sheet, and is directed to the rear surface of the liquid crystal display panel 94. The light source, the reflection sheet 91, and the light guide plate 92 configure the light source unit.

The liquid crystal display panel 94 modulates the light directed to the rear surface thereof, the modulated light passes through the liquid crystal display panel 94, and therefore an image is displayed on the display surface of the liquid crystal display panel 94.

The peripheral edge part of an upper side of the liquid crystal display panel 94 is covered by a cover section 95. The cover section 95 is a section of the cover which covers the peripheral edge part of the liquid crystal display panel 94. The cover section 95 is manufactured by extrusion molding.

The cover section 95 has: a rectangular plate-like front wall 95a covering the front side of the liquid crystal display panel 94; an upper wall 95b that protrudes rearward from the upper side of the front wall 95a, and covers an upper end surface of the liquid crystal display panel 94; and two rectangular plate-like protrusions 95c and 95d protruding rearward from a middle part of the front wall 95a parallel to the upper wall 95b. The protrusion 95c is disposed at the upper side than the protrusion 95d. A groove 95e is formed between the protrusions 95c and 95d.

While the side wall 90b of the backlight chassis 90 is placed between the upper wall 95b and the protrusion 95c, the cover section 95 is fitted into the backlight chassis 90 from the front side. At this time, a lower portion of the front wall 95a abuts the display surface of the liquid crystal display panel 94 through an elastic member 96, and covers the peripheral edge part of the display surface.

In the bottom plate 90a of the backlight chassis 90, a screw through hole 90c is provided at a position facing the groove 95e of the cover section 95. The cover section 95 and the backlight chassis 90 are fixed by screwing a screw 97 passed through the screw through hole 90c to the groove 95e.

The liquid crystal display apparatus 9 having the above-described configuration can be manufactured at low cost, since the cover sections 95 configuring the cover are formed by extrusion molding. Furthermore, since the backlight chassis 90 also serves as a role of the cabinet, it is also possible to meet the requirements of being thinner and lighter.

### SUMMARY

However, the liquid crystal display apparatus 9 having the above-described configuration includes the groove 95e for fixing the cover section 95 to the backlight chassis 90 by screwing, on the front wall 95a of the cover section 95. Thus, there is a problem that the front wall 95a fringing the display surface of the liquid crystal display panel 94 has a large width and the liquid crystal display apparatus 9 has a deteriorated appearance.

A similar problem also arises in a display apparatus including, as a display panel, a plasma display panel, an organic EL (electro luminescence) display panel, or the like.

The present invention has been made in view of the circumstances as described above. An object of the present invention is to provide a display apparatus and television receiver, with a cover having a narrow width portion fringing a display surface of a display panel and the appearance thereof being preferable.

The display apparatus according to the present invention includes an exterior body that surrounds a peripheral surface of a display panel for displaying an image, and a cover that covers a peripheral edge part of the display panel from an outside of the exterior body. The cover is configured by a plurality of cover sections, each of which covers a portion of the peripheral edge part of the display panel. At least one of the plurality of cover sections is provided with an inward protrusion. A portion of the exterior body is provided with one or more insertion holes of a number equal to or larger than the number of the protrusions, the portion surrounding the peripheral face of the display panel. The protrusion is fixed with inserted into the insertion hole.

According to the present invention, the cover covers the peripheral edge part of the display panel from the outside of the exterior body that surrounds the peripheral surface of the display panel for displaying an image. The cover is configured by the plurality of cover sections, each of which covers a portion of the peripheral edge part of the display panel. The inward protrusion provided on at least one of the plurality of cover sections is inserted into one of one or more insertion holes of a number equal to or larger than the number of the protrusions and then is fixed to a portion of the exterior body surrounding the peripheral surface of the display panel.

It is thus unnecessary to provide a groove for fixing the cover section to the exterior body on a portion of the cover section facing the surface of the display panel. Therefore, the cover can have a narrow width portion fringing the display panel while the display apparatus can have a preferable appearance.

In the display apparatus according to the present invention, the insertion hole has: a first hole that has a rectangular cross-section; and a second hole that has a smaller rectangular cross-section than the cross-section of the first hole and is formed continuously to one side of the first hole. The protrusion has a locking claw at a tip end portion thereof and is fixed by the locking claw locked to an edge part of the second hole.

According to the present invention, the protrusion is fixed by locking the locking claw provided on the tip end portion thereof to the edge part of the second hole having a rectangular cross-section. The second hole is formed continuously to one side of the first hole having a larger rectangular cross-section than the cross-section of the second hole.

The protrusion is slid to the second hole after the protrusion is inserted into the first hole. Thus the protrusion can be easily fixed with inserted into the insertion hole. In addition, a fixture, for example, a screw used for fixing the protrusion is unnecessary, and therefore, the number of components of the display apparatus can be low. Furthermore, time and effort required for manufacturing the display apparatus can be reduced, and the display apparatus can be manufactured at low cost.

In the display apparatus according to the present invention, the exterior body covers an opposite surface of a display surface of the display panel for displaying an image. A portion of the exterior body and the protrusion are fixed to each other by a screw, the portion covering the opposite surface.

According to the present invention, the exterior body surrounds the peripheral surface of the display panel, as well as covers the opposite surface of the display surface of the display panel for displaying an image. The protrusion is inserted into the insertion hole provided at the portion of the exterior body surrounding the peripheral surface of the display panel, and then is reliably fixed by a screw to the portion of the exterior body covering the opposite surface of the display surface of the display panel.

A television receiver includes: the above-described display apparatus; and a receiving unit that receives television broadcast. An image is displayed on the display apparatus based on the television broadcast received by the receiving unit.

According to the present invention, an image based on the television broadcasts received by the receiving unit is displayed on the above-described apparatus. Therefore, the image based on the television broadcast is displayed on the display apparatus having preferable appearance.

According to the present invention, the protrusion provided on the cover section that covers a portion of the peripheral edge part of the display panel is inserted into the insertion hole provided on the portion of the exterior body surrounding the peripheral surface of the display panel and then is fixed. Therefore, the cover can have a narrow width portion fringing the display surface of the display panel while the appearance can be preferable.

The above and further objects and features will move fully be apparent from the following detailed description with accompanying drawings.

### BRIEF DESCRIPTION OF THE DRAWINGS

FIG. 1 is a longitudinal cross-sectional view illustrating a display apparatus as an example;

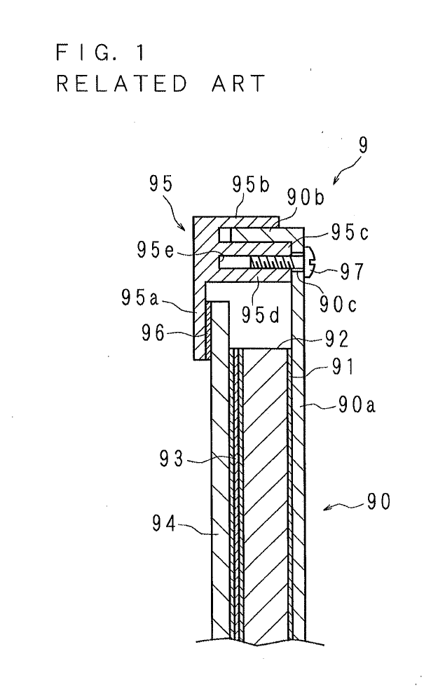

FIG. 2 is a schematic view illustrating an appearance of a television receiver according to Embodiment 1 of the present invention;

FIG. 3 is a front view illustrating a state in which cover sections are separated and removed;

FIG. 4 is a rear view illustrating the state in which the cover sections are separated and removed;

FIG. 5 is a cross-sectional view of the cover section;

FIG. 6 is a partially enlarged perspective view of the cover sections and a backlight chassis;

FIG. 7 is a view describing an attaching procedure of the cover section;

FIG. 8 is a view describing the attaching procedure of the cover sections;

FIG. 9 is a perspective view illustrating an attached state of the cover sections;

FIG. 10 is a view describing the attaching procedure of the cover section;

FIG. 11 is a perspective view illustrating the attached state of the cover sections;

FIG. 12 is a longitudinal cross-sectional view of a display apparatus;

FIG. 13 is a longitudinal cross-sectional view of the display apparatus;

FIG. 14 is a transverse cross-sectional view of a right portion of the display apparatus;

FIG. 15 is a transverse cross-sectional view of the right portion of the display apparatus;

FIG. 16 is a cross-sectional view of a cover section according to Embodiment 2;

FIG. 17 is a partially enlarged perspective view of cover sections and the backlight chassis;

FIG. 18 is a view describing an attaching procedure of the cover sections;

FIG. 19 is a longitudinal cross-sectional view of the display apparatus; and

FIG. 20 is a transverse cross-sectional view of the right portion of the display apparatus.

### DETAILED DESCRIPTION OF NON-LIMITING EXAMPLE EMBODIMENTS

The present invention will now be described below with reference to the drawings illustrating embodiments thereof.

### Embodiment 1

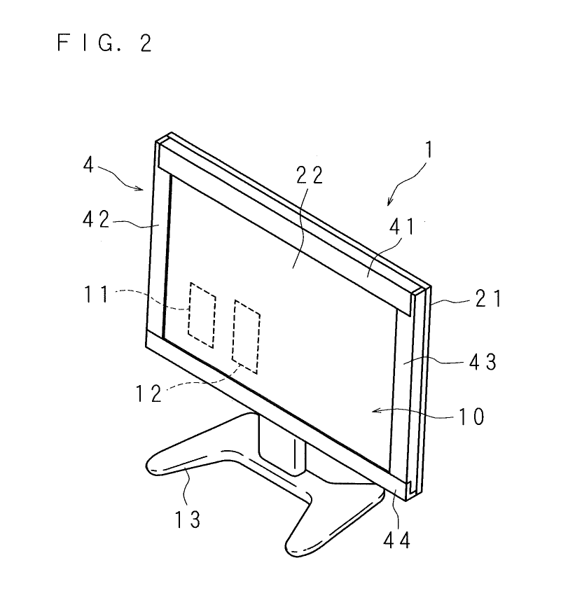

FIG. 2 is a schematic view illustrating an appearance of a television receiver according to Embodiment 1 of the present invention. The television receiver 1 includes a display apparatus 10, a receiving unit 11, a signal processing unit 12, and a stand 13.

The display apparatus 10 includes a rectangular plate-like display panel 22 on which an image is displayed. A peripheral edge part of the display panel 22 is covered by a cover 4, while a display surface of the display panel 22 for displaying the image is exposed to an outside. The cover 4 is configured by cover sections 41, 42, 43 and 44 corresponding to respective sides of the display panel 22.

In addition, an opposite surface of the display surface of the display panel 22 is covered by a backlight chassis 21. The backlight chassis 21 supports a light source unit which will be described below, and functions as an exterior body of the display apparatus 10.

The receiving unit 11 is connected to an antenna (not illustrated), and receives television broadcast through the antenna. The signal processing unit 12 demodulates data concerning the television broadcast received by the receiving unit 11, separates image data from the demodulated data, and outputs the separated image data. In the display panel 22, an image based on the image data output from the signal processing unit 12 is displayed on the display surface.

The stand 13 is provided so as to protrude from an outside of the backlight chassis 21, and is placed on a placing surface, for example, a floor surface. The display apparatus 10 is supported by the stand 13 so that the display surface of the display panel 22 is perpendicular to the placing surface, and then is used. Regarding the display apparatus 10 in a use state, the stand 13 side will be referred to as a lower side, and the display panel 22 side will be referred to as a front side. In addition, left and right sides of the display surface of the display panel 22 when viewed from the front side will be referred to as left and right sides of the display apparatus 10.

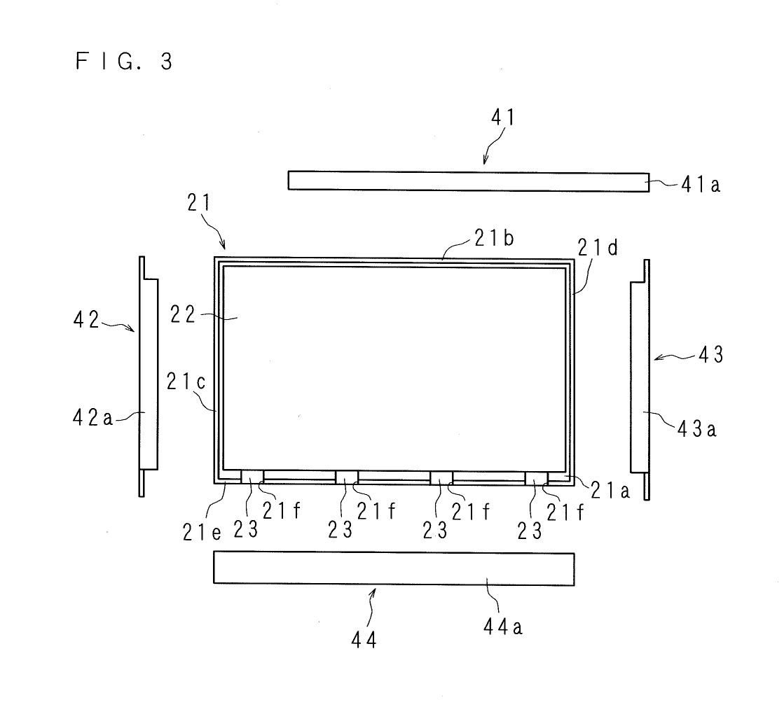

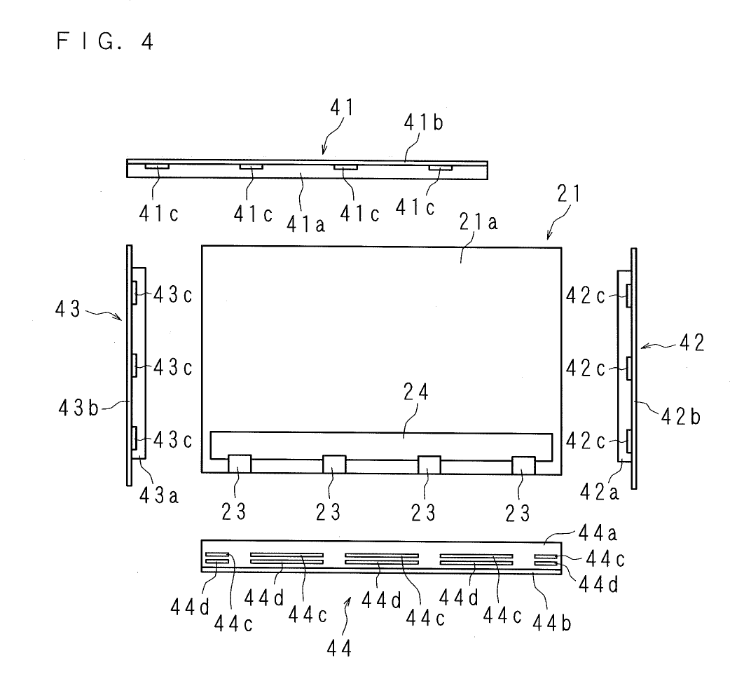

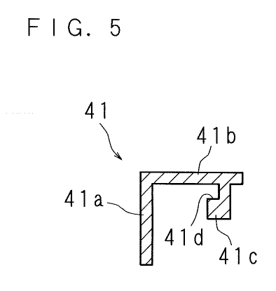

FIG. 3 is a front view illustrating a state in which the cover sections 41, 42, 43 and 44 are separated and removed, FIG. 4 is a rear view illustrating the state in which the cover sections 41, 42, 43 and 44 are separated and removed, and FIG. 5 is a cross-sectional view of the cover section 41.

It is noted that FIG. 3 illustrates the backlight chassis 21, the display panel 22, and FPCs (flexible printed circuits) 23, 23, 23 and 23 which will be described later, as well as the cover sections 41, 42, 43 and 44 when viewed from the front side. FIG. 4 illustrates the backlight chassis 21, the FPCs 23, 23, 23 and 23, and a control circuit 24 which will be described later, as well as the cover sections 41, 42, 43 and 44 when viewed from the rear side.

The cover 4 is configured by the cover sections 41, 42, 43 and 44, as described above. The cover sections 41, 42, 43 and 44 are disposed at upper, left, right and lower sides of the display panel 22, respectively.

The upper cover section 41 is formed to have a bar-like shape and has a cross-section as illustrated in FIG. 5. The cover section 41 has a front wall 41a, and an upper wall 41b protruding rearward from an upper side of the front wall 41a. Four protrusions 41c, 41c, 41c and 41c protruding parallel to the front wall 41a are provided on the upper wall 41b at appropriate intervals along the upper side of the front wall 41a, as illustrated as FIGS. 4 and 5.

The protrusion 41c is formed to have a rectangular plate-like shape with a longitudinal direction corresponding to a horizontal direction. The protrusion 41c has a locking claw 41d protruding to the front side on a tip end portion thereof.

Each of the left cover section 42 and the right cover sections 43 has the similar cross-section as the cover section 41. The cover section 42 has a front wall 42a, a left wall 42b protruding rearward from the left side of the front wall 42a, and three protrusions 42c, 42c and 42c protruding from the left wall 42b parallel to the front wall 42a. The cover section 43 has a front wall 43a, a right wall 43b protruding rearward from the right side of the front wall 43a, and three protrusions 43c, 43c and 43c protruding from the right wall 43b parallel to the front wall 43a.

As illustrated in FIG. 4, the three protrusions 42c, 42c and 42c are disposed at appropriate intervals along the left side of the front wall 42a, and the three protrusions 43c, 43c and 43c are disposed at appropriate intervals along the right side of the front wall 43a. Each of the protrusions 42c and 43c has a locking claw formed to have the similar shape as the locking claw 41d on the tip end portion thereof.

The cover section 42 has, as illustrated in FIGS. 3 and 4, cutouts at the upper and lower end portions, respectively. The cutout provided at the upper end portion is formed by cutting out the front wall 42a, and the cutout provided at the lower end portion is formed by cutting out the front wall 42a and a front portion of the left wall 42b.

The cover section 43 also has cutouts similarly to the cover section 42 at each of the upper and lower end portions. The cutout provided at the upper end portion is formed by cutting out the front wall 43a, and the cutout provided at the lower end portion is formed by cutting out the front wall 43a and the front portion of the right wall 43b.

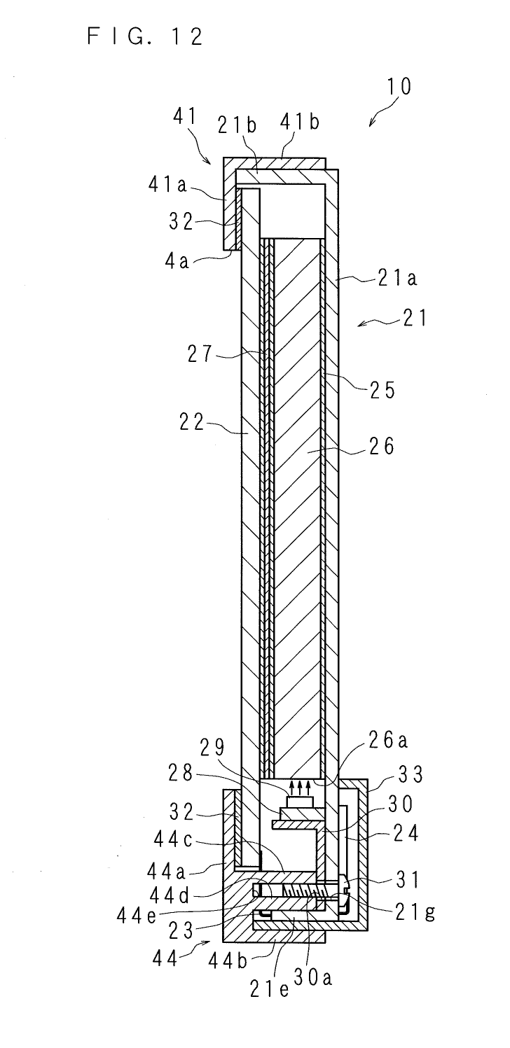

The lower cover section 44 has a front wall 44a, and a lower wall 44b protruding rearward from the lower side of the front wall 44a (see FIG. 12). Linear projections 44c, 44c, . . . , 44c and 44d, 44d, . . . , 44d projecting parallel to the lower wall 44b are provided at appropriate intervals on a middle part of the front wall 44a along the lower side of the lower wall 44b, as illustrated in FIG. 4. The linear projections 44c, 44c, . . . , 44c are respectively adjacent to the linear projections 44d, 44d, . . . 44d.

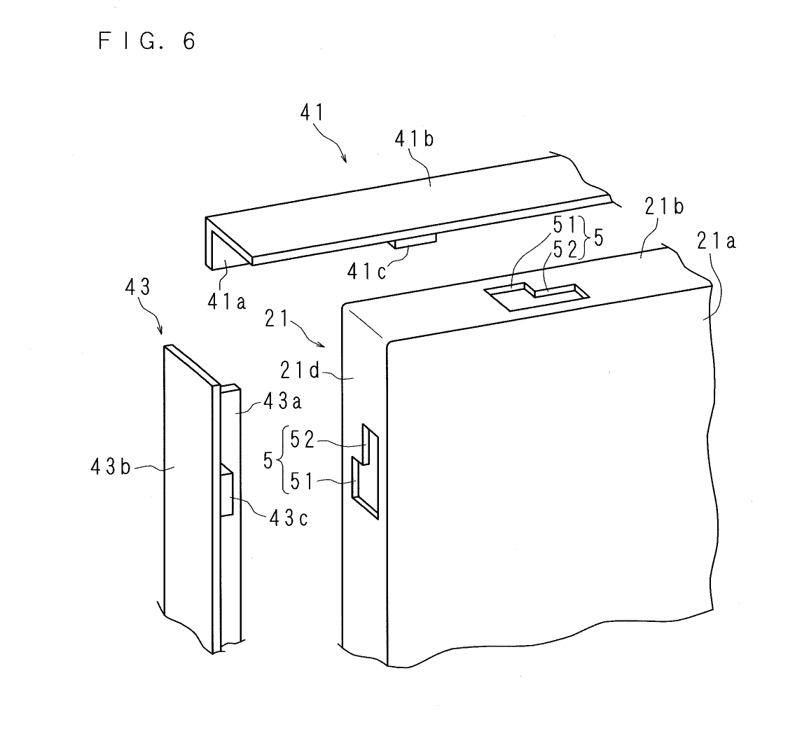

FIG. 6 is a partially enlarged perspective view of the cover sections 41 and 43 and the backlight chassis 21. FIG. 6 illustrates a right portion of the cover section 41, an upper portion of the cover section 43, and an upper right portion of the backlight chassis 21 when viewed from the upper right rear.

As illustrated in FIGS. 3 and 6, the backlight chassis 21 has a rectangular plate-like bottom plate 21a and further has an upper wall 21b, a left wall 21c, a right wall 21d and a lower wall 21e which extend from the upper, left, right and lower sides of the bottom plate 21a to the front side, respectively. The backlight chassis 21 is formed to have a box-like shape with one surface opened as a whole. The upper wall 21b, the left wall 21c, the right wall 21d and the lower wall 21e have substantially the same height.

An insertion hole 5 is provided in the upper wall 21b. The insertion hole 5 has a first hole 51 and a second hole 52. As illustrated in FIG. 6, each of the first hole 51 and the second hole 52 has a rectangular cross-section. The longitudinal direction of the first hole 51 corresponds to that of the second hole 52.

The second hole 52 is formed continuously to one short side of the first hole 51 and extends in the longitudinal direction of the first hole 51. The width of the first hole 51 is wider than the width of the second hole 52, and the second hole 52 has smaller size than the first hole. The first hole 51 is provided at the right side, and the second hole 52 is provided at the left side.

The first hole 51 has a width and length suitable for a tip end portion of the protrusion 41c to be inserted thereinto, and the second hole 52 has a width in which the locking claw 41d provided on the tip end portion of the protrusion 41c is locked to an edge part of the second hole 52.

The protrusion 41c is slid to the second hole 52 side after the protrusion 41c is inserted into the first hole 51. Thus, the locking claw 41d provided on the protrusion 41c can be locked to the edge part of the second hole 52, and the protrusion 41c can be easily fixed. The protrusion 41c is fixed by locking the locking claw 41d locked to the edge part of the second hole 52.

FIG. 6 illustrates the insertion hole 5 located at a right side of the upper wall 21b, and the insertion holes 5 are provided at four places of the upper wall 21b corresponding to the protrusions 41c, 41c, 41c and 41c.

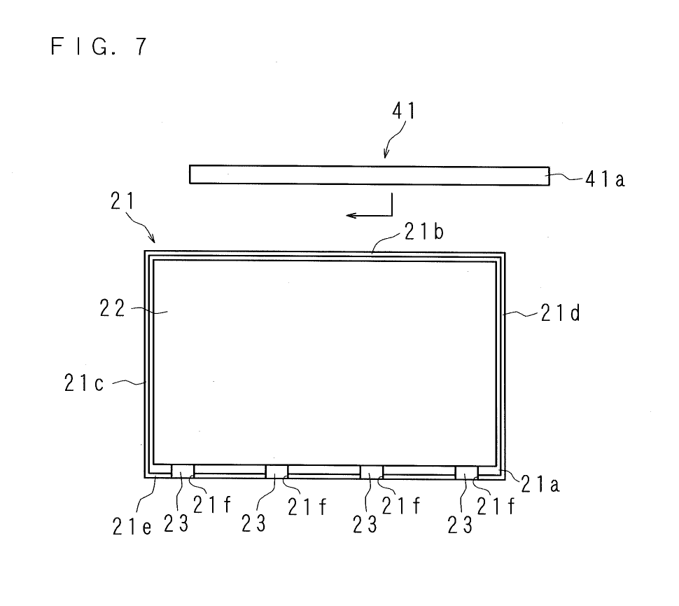

FIG. 7 is a view describing an attaching procedure of the cover section 41. When attaching the cover section 41 to the upper wall 21b of the backlight chassis 21, as indicated by an arrow in FIG. 7, the protrusions 41c, 41c, 41c and 41c of the cover section 41 are inserted into the first holes 51, 51, 51 and 51 provided in the upper wall 21b, and then the cover section 41 is slid to the left side of the backlight chassis 21. Thereby, the cover section 41 is attached to the upper wall 21b of the backlight chassis 21, since the locking claw 41d provided on the protrusion 41c is locked to the edge part of the second hole 52.

As illustrated in FIG. 6, the insertion hole 5 is also provided in the right wall 21d of the backlight chassis 21. Regarding the insertion hole 5 provided in the right wall 21d, the first hole 51 is formed at the lower side, and the second hole 52 is formed at the upper side.

As described above, the protrusion 43c is formed to have the similar shape as the protrusion 41c. Accordingly, the cover section 43 is slid to the second hole 52 side after the protrusion 43c is inserted into the first hole 51 Thus, the locking claw 43d provided on the protrusion 43c can be locked to the edge part of the second hole 52, and the protrusion 43c can be easily fixed. The protrusion 43c is fixed by locking the locking claw 43d to the edge part of the second hole 52.

FIG. 6 illustrates the insertion hole 5 located at an upper side of the right wall 21d, and the insertion holes 5 are provided at three places of the right wall 21d corresponding to the protrusions 43c, 43c and 43c.

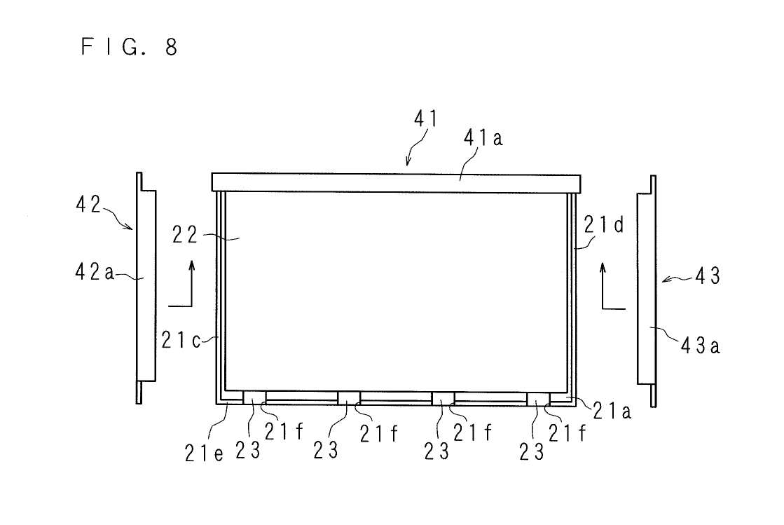

FIG. 8 is a view describing the attaching procedure of the cover sections 42 and 43. Attaching of the cover sections 42 and 43 is performed after the cover section 41 is attached to the upper wall 21b of the backlight chassis 21 as illustrated in FIG. 8. After the cover section 41 is attached to the upper wall 21b, both ends of the cover section 41 slightly protrude from the backlight chassis 21.

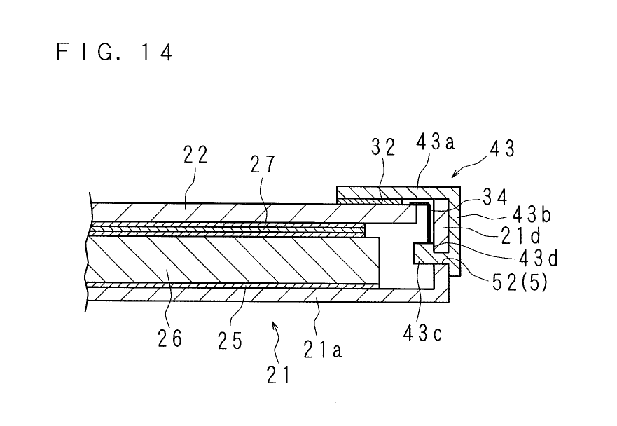

When attaching the cover section 43 to the right wall 21d of the backlight chassis 21, as indicated by an arrow in FIG. 8, the protrusions 43c, 43c and 43c of the cover section 43 are inserted into the first holes 51, 51 and 51 provided in the right wall 21d, and then the cover section 43 is slid to the upper wall 21b side of the backlight chassis. Thereby, the cover section 43 is attached to the right wall 21d of the backlight chassis 21, since the locking claw 43d (see FIG. 14) provided on the protrusion 41c is locked to the edge part of the second hole 52.

Three insertion holes 5, 5 and 5 are also provided in the left wall 21c of the backlight chassis 21 as well as in the right wall 21d, and the cover section 42 is attached to the left wall 21c of the backlight chassis 21 in the similar manner as the cover section 43.

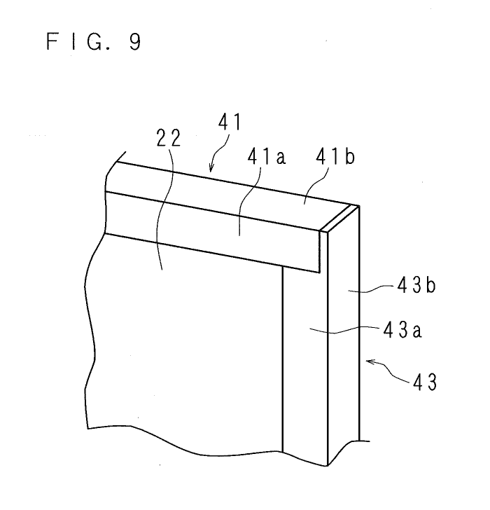

FIG. 9 is a perspective view illustrating an attached state of the cover sections 41 and 43. FIG. 9 illustrates an enlarged upper right portion of the display apparatus 10 illustrated in FIG. 2. The cutout provided at the upper end portion of the cover section 43 abuts the right end portion of the front wall 41a of the cover section 41. In addition, the right wall 43b of the cover section 43 abuts the upper wall 41b of the cover section 41.

The attached state of the cover sections 41 and 42 is similar to the attached state of the cover sections 41 and 43. The cutout provided at the upper end portion of the cover section 42 abuts the left end portion of the front wall 41a of the cover section 41, and the left wall 42b of the cover section 42 abuts the upper wall 41b of the cover section 41.

As described above, the cover section 41 can be fixed with prevented from movement to left side or right side and without using a fixture, for example, a screw, since each of the both ends of the cover section 41 abuts the cover sections 42 and 43.

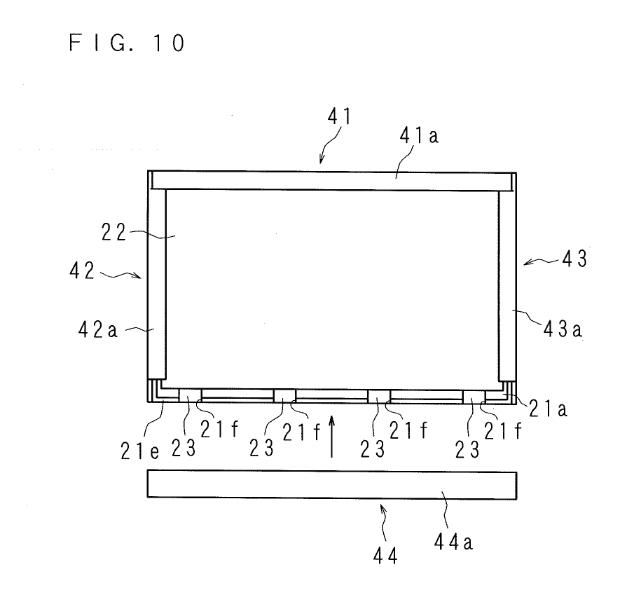

FIG. 10 is a view describing the attaching procedure of the cover section 44. Attaching of the cover section 44 is performed after cover sections 41, 42 and 43 are attached as illustrated in FIG. 10.

The cover section 44 is fitted to the backlight chassis 21 from the front side so as to cover the lower side of the display panel 22. A screw 31 inserted from an outside into the bottom plate 21a of the backlight chassis 21, which will be described later, is screwed to a groove 44e provided between the linear projections 44c and 44d, which will be described later. Thus the cover section 44 fitted to the backlight chassis 21 is fixed to the bottom plate 21a (see FIG. 12).

When the cover section 44 is fitted to the backlight chassis 21 from the front side, the linear projections 44c, 44c, . . . , 44c, and 44d, 44d, . . . , 44d illustrated in FIG. 4 are disposed at position not overlapping with the FPCs 23, 23, 23 and 23 illustrated in FIG. 3.

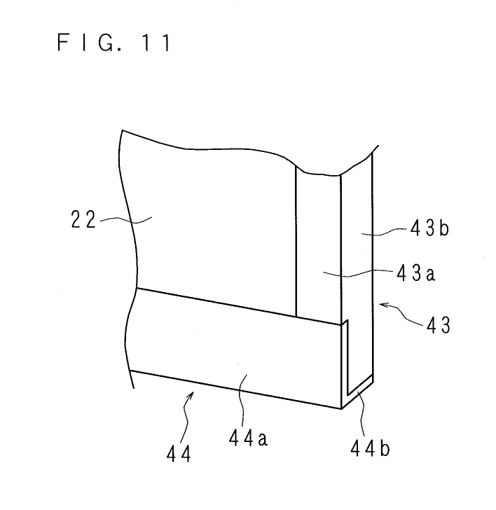

FIG. 11 is a perspective view illustrating the attached state of the cover sections 43 and 44. FIG. 11 illustrates an enlarged right lower portion of the display apparatus 10 illustrated in FIG. 2. The cutout provided at the lower end portion of the cover section 43 abuts each of the front wall 44a and the lower wall 44b of the cover section 44. In addition, the right wall 43b of the cover section 43 abuts the lower wall 44b of the cover section 44. Therefore, downward movement of the cover section 43 is prevented, while a position of the cover section 43 is determined.

The attached state of the cover sections 42 and 44 is similar to the attached state of the cover sections 43 and 44. The cutout provided at the lower end portion of the cover section 42 abuts the front wall 44a and the lower wall 44b of the cover section 44, and the left wall 42b of the cover section 42 abuts the lower wall 44b of the cover section 44. Therefore, downward movement of the cover section 43 is prevented, while the position of the cover section 42 is determined.

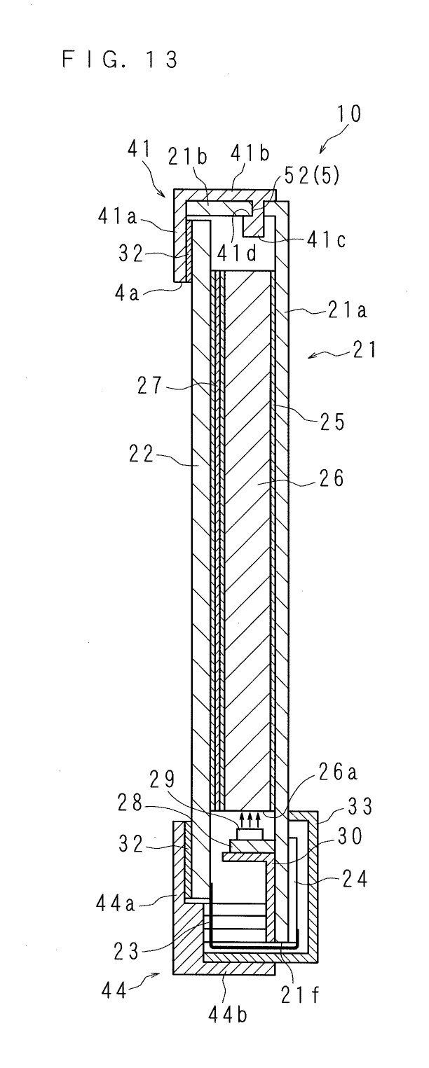

FIGS. 12 and 13 are longitudinal cross-sectional views of the display apparatus 10. FIG. 12 illustrates the cross-section of the display apparatus 10 at a position where the protrusion 41c is not disposed, and FIG. 13 illustrates the cross-section of the display apparatus 10 at a position where the protrusion 41c is disposed.

A rectangular reflection sheet 25, a rectangular plate-like light guide plate 26, an optical sheet group 27 including similar rectangular optical sheets, and the display panel 22 are laminated in close contact in order from the rear side to the front side, on the bottom plate 21a of the backlight chassis 21.

The upper wall 21b, the left wall 21c, right wall 21d and lower wall 21e of the backlight chassis 21 surrounds the peripheral surface of the display panel 22, as illustrated in FIGS. 3, 12 and 13. The bottom plate 21a of the backlight chassis 21 covers the rear surface of the display panel 22.

A rectangular plate-like LED (light emitting diode) substrate 28 with a longitudinal direction corresponding to the horizontal direction is disposed at the lower side of a lower end surface 26a of the light guide plate 26. LEDs 29, 29, . . . , 29 (only one is illustrated in FIGS. 12 and 13) are installed on the upper surface of the LED substrate 28 at appropriate intervals in the longitudinal direction of the LED substrate 28. Each of the LEDs 29, 29, . . . , 29 emits light toward the lower end surface 26a of the light guide plate 26 in a direction indicated by arrows in FIGS. 12 and 13.

A heat dissipation part 30 is in close contact with the lower surface of the LED substrate 28. The heat dissipation part 30 is formed by connecting two rectangular plate-like flat plates, each of which has a longitudinal direction corresponding to the horizontal direction, at the one long side of each of the two flat plates, and the cross-section of the heat dissipation part 30 is formed to have an L shape.

One flat plate of the heat dissipation part 30 is in close contact with the bottom plate 21a of the backlight chassis 21 so that the other flat plate thereof is located at an upper side. The LED substrate 28 is installed on the upper side of the other flat plate of the heat dissipation part 30.

The light guide plate 26 is made of acrylic resin, for example. The light emitted from each of the LEDs 29, 29, . . . , 29 enters into the light guide plate 26 from the lower end surface 26a. The light which has entered into the light guide plate 26 propagates through the light guide plate 26 with reflected repeatedly on the front and rear surfaces.

The light is totally reflected on the rear surface of the light guide plate 26 by an operation of the reflection sheet 25 disposed on the rear side of the light guide plate 26. The light is partially reflected on the front surface of the light guide plate 26, and thus a part of the light propagating through the light guide plate 26 is emitted to the outside. The light which has entered into the light guide plate 26 is repeatedly reflected on the front and rear surfaces as described above so that the light is uniformly emitted from the front surface of the light guide plate 26.

The light emitted from the front surface of the light guide plate 26 passes through the optical sheet group 27 and is directed to the rear surface of the display panel 22. The LEDs 29, 29, . . . , 29, the reflection sheet 25, and the light guide plate 26 configure the light source unit for irradiating light to the display panel 22. The optical sheet group 27 is composed of multiple laminated optical sheets including, for example, a view expansion sheet and an anti-reflection sheet and having various optical functions.

The display panel 22 is configured by filling liquid crystal between a color filter substrate disposed at the front side and an array substrate disposed at the rear side. One end of each of the rectangular sheet-like FPCs 23, 23, 23 and 23 is connected to the lower side portion of the display panel 22 at appropriate intervals, as illustrated in FIG. 3. A driving circuit (not illustrated) applying voltage to the liquid crystal filled between the color filter substrate and the array substrate so as to drive the display panel 22 is mounted on each of the FPCs 23, 23, 23 and 23.

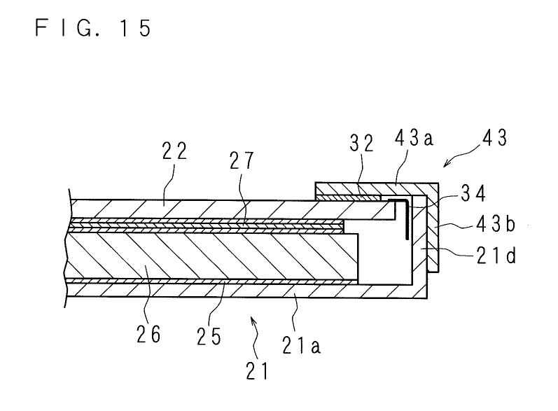

FPCs 34, 34, . . . , 34 (see FIGS. 14 and 15) which will be described later are provided on each of left and right side portions of the display panel 22. Also, a driving circuit (not illustrated) applying voltage to the liquid crystal filled between the color filter substrate and the array substrate so as to drive the display panel 22 is mounted on each of the FPCs 34, 34, . . . , 34 in the similar manner as the FPC 23.

The driving circuit mounted on each of the FPCs 23, 23, 23, 23 and 34, 34, . . . , 34 applies voltage to the liquid crystal so that the light directed to the rear surface of the display panel 22 is modulated in the display panel 22. Thus, the display panel 22 transmits or blocks the light entering from the rear surface of the display panel 22 so that an image is displayed on the display surface of the display panel 22.

On an edge of the lower wall 21e of the backlight chassis 21, four cutouts 21f, 21f, 21f and 21f are provided at respective positions corresponding to the FPCs 23, 23, 23 and 23, as illustrated in FIGS. 3 and 13. Each of the FPCs 23, 23, 23 and 23 hanging down from the lower side portion of the display panel 22 is bent rearward, in a state of individually passing through the cutouts 21f, 21f, 21f and 21f, as illustrated in FIGS. 3 and 13. The other end of each of the FPCs 23, 23, 23 and 23 is connected to the control circuit 24, as illustrated in FIGS. 4 and 13. The control circuit 24 is covered by a circuit cover 33.

The control circuit 24 indicates the voltage to be applied to the liquid crystal by the driving circuits of the FPCs 23, 23, 23 and 23 based on image data output from the signal processing unit 12. Thereby, an image based on image data output from the signal processing unit 12 is displayed on the display surface of the display panel 22. The control circuit 24 is attached at the lower side of the rear surface of the bottom plate 21a.

The lower portion of the front wall 41a of the cover section 41 and the upper portion of the front wall 44a of the cover section 44 abut the display surface of the display panel 22 through elastic members 32 and 32 for inhibiting damage to the display panel 22, and respectively cover the upper and lower sides of the display surface of the display panel 22. The upper wall 41b of the cover section 41 and the lower wall 44b of the cover section 44 respectively cover the upper and lower end surfaces of the display panel 22 from the outside of the backlight chassis 21.

In the upper wall 21b of the backlight chassis 21, the insertion holes 5, 5, 5 and 5 are disposed at the rear side of the display panel 22. The locking claws 41d, 41d, 41d and 41d respectively formed on the protrusions 41c, 41c, 41c and 41c of the cover section 41 are respectively locked, in a space formed at the rear side of the display panel 22, to the edge parts of the insertion holes 5, 5, 5 and 5 provided in the upper wall 21b. Therefore, the cover section 41 is attached to the upper wall 21b of the backlight chassis 21. Each of the protrusions 41c, 41c, 41c and 41c protrudes inward from the upper wall 41b in the display apparatus 10, as illustrated in FIG. 13.

The linear projections 44c and 44d provided on the front wall 44a of the cover section 44 are formed to have rectangular plate-like shape, as illustrated in FIGS. 4 and 12. The groove 44e is provided continuously in the horizontal direction between the linear projections 44c and 44d. The bottom plate 21a of the backlight chassis 21 and the one flat plate of the heat dissipation part 30 are respectively provided with screw through holes 21g and 30a at positions facing the groove 44e.

A screw 31 passed through the screw through holes 21g and 30a from the rear side of the backlight chassis 21 is screwed to the groove 44e of the cover section 44. Thus, each of the heat dissipation part 30 and the cover section 44 is fixed to the bottom plate 21a of the backlight chassis 21.

FIGS. 14 and 15 are transverse cross-sectional views of the right portion of the display apparatus 10. A plurality of FPCs 34, 34, . . . , 34 (only one is illustrated in FIGS. 14 and 15) are disposed on the right side portion of the display panel 22 as well as on the lower side portion of the display panel 22. FIG. 14 illustrates a cross-section of the display apparatus 10 at a position where the FPC 34 is not connected to the right side portion of the display panel 22, and FIG. 15 illustrates a cross-section of the display apparatus 10 at a position where the FPC 34 is connected to the right side portion of the display panel 22.

A left portion of the front wall 43a of the cover section 43 abuts the display surface of the display panel 22 through the elastic member 32 and covers the right side of the display surface of the display panel 22. The right wall 43b of the cover section 43 covers the right end surface of the display panel 22 from the outside of the backlight chassis 21.

One end of each of the FPCs 34, 34, . . . , 34 is connected to the right side portion of the display panel 22, and the FPCs 34, 34, . . . , 34 are bent rearward.

In the right wall 21d of the backlight chassis 21, each of the insertion holes 5, 5 and 5 is disposed at the rear side of the display panel 22. The locking claws 43d, 43d and 43d respectively formed on the protrusions 43c, 43c and 43c of the cover section 43 are respectively locked, in the space formed at the rear side of the display panel 22, to the edge parts of the insertion holes 5, 5 and 5 provided in the right wall 21d. Therefore, the cover section 43 is attached to the right wall 21d of the backlight chassis 21. Each of the protrusions 43c, 43c and 43c protrudes inward from the right wall 43b in the display apparatus 10, as illustrated in FIG. 14.

The FPCs 34, 34, . . . , 34 connected to the right side portion of the display panel 22 are disposed at positions not overlapping with the protrusions 43c, 43c and 43c.

The transverse cross-section of the left portion of the display apparatus 10 is similar to the transverse cross-section of the right portion of the display apparatus 10 illustrated in FIGS. 14 and 15. The cover section 42 is attached to the left wall 21c of the backlight chassis 21 similarly to the cover section 43.

As described-above, the protrusions 41c, 42c and 43c respectively provided on the cover sections 41, 42 and 43 respectively covering the upper, left and right side portions of the display panel 22 are inserted into the insertion holes 5, 5, . . . , 5 provided in the upper wall 21b, the left wall 21c and the right wall 21d of the backlight chassis 21, and then are fixed.

Accordingly, the upper cover section 41, the left cover section 42, and the right cover section 43 has no groove for fixing the cover sections 41, 42 and 43 to the backlight chassis 21 by screwing, on the front walls 41a, 42a and 43a. Therefore, the width of the front walls 41a, 42a and 43a fringing the display surface of a display panel 22 can be narrow while the appearance can be preferable.

Further, when attaching the cover sections 41, 42 and 43 to the backlight chassis 21, it is unnecessary to use a fixture, for example, a screw, for fixing the protrusions 41c, 42c and 43c. Therefore, the number of components of the display apparatus 10 can be low, time and effort required for manufacturing the display apparatus 10 can be reduced, and the display apparatus 10 can be manufactured at low cost.

In addition, the backlight chassis 21 which supports the display panel 22, the reflection sheet 25, the optical sheet group 27, and the light guide plate 26, or the like, configures a part of the display apparatus 10 as an exterior body, and there is no member covering the entirety of the backlight chassis 21. Therefore, it is possible to meet the requirements of being thinner and lighter regarding the display apparatus 10 and the television receiver 1 including the display apparatus 10.

It is noted that the shape of the first hole 51 and the second hole 52 are not limited to the rectangular shape. The first hole 51 may be any shape suitable for each tip end portion of the protrusions 41c, 42c and 43c to be inserted thereinto. The second hole 52 may be any shape suitable for the locking claw provided on each of the protrusions 41c, 42c and 43c to be locked to the edge part of the second hole 52.

In addition, the shapes of the protrusions 41c, 42c and 43c are not limited to the shapes described in Embodiment 1.

Furthermore, the number of the insertion holes 5 provided in each of the upper wall 21b, the left wall 21c and the right wall 21d of the backlight chassis 21 may be equal to or larger than the number of the protrusions 41c, 42c and 43c. The number of the protrusions 41c is not limited to four and may be any appropriate number capable of being disposed within the length range of the upper wall 41b. Similarly, the number of each of the protrusions 42c and 43c is not limited to three and may be any appropriate number capable of being disposed within the length range of the left wall 42b and the right wall 43b.

In addition, there is no need to provide the protrusion on all of the cover sections 41, 42 and 43, and the protrusion may be provided on at least one of the cover sections 41, 42, and 43.

### Embodiment 2

A television receiver 1 according to Embodiment 2 is different in the shape of the protrusions provided on each of the cover sections 41, 42 and 43, and the shape of the insertion holes provided in each of the upper wall 21b, the left wall 21c and the right wall 21d of the backlight chassis 21, compared to the television receiver 1 according to Embodiment 1.

Hereinafter, the protrusions and the insertion holes according to Embodiment 2 will be described, and the components common to Embodiment 1 are denoted by the same reference codes and will not be described in detail.

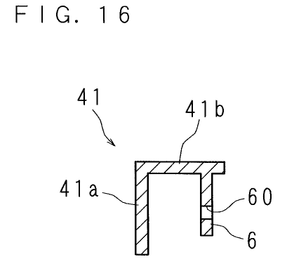

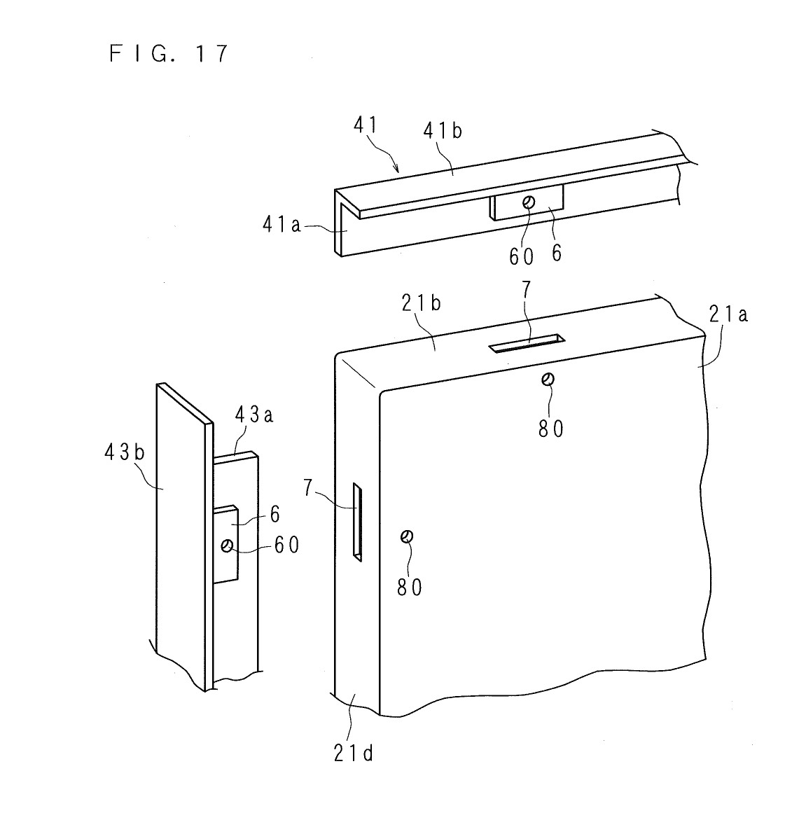

FIG. 16 is a cross-sectional view of a cover section 41 according to Embodiment 2, and FIG. 17 is a partially enlarged perspective view of cover sections 41 and 43 and the backlight chassis 21. FIG. 17 illustrates a right portion of the cover section 41, an upper portion of the cover section 43, and an upper right portion of the backlight chassis 21 when viewed from the upper right rear.

On an upper wall 41b of the cover section 41, a protrusion 6 protruding parallel to a front wall 41a is provided. The protrusion 6 provided on the upper wall 41b is formed to have a rectangular plate-like shape with a longitudinal direction corresponding to the horizontal direction and has a screw hole 60 penetrating in a front and rear direction at a middle part of the longitudinal direction of the protrusion 6.

FIG. 17 illustrates the protrusion 6 to be located at a right side of the upper wall 21b, and the protrusions 6 are provided at four places of the upper wall 41b on which the protrusions 41c, 41c, 41c and 41c are disposed in Embodiment 1.

Each of the cover sections 42 and 43 has the similar cross-section as the cover section 41 illustrated in FIG. 16. Each of front walls 42a and 43a corresponds to the front wall 41a, and each of the left wall 42b and right wall 43b corresponds to the upper wall 41b.

On a right wall 43b of the cover section 43, a protrusion 6 protruding parallel to the front wall 43a is also provided. The protrusion 6 provided on the right wall 43b is formed to have a rectangular plate-like shape with a longitudinal direction corresponding to a vertical direction and has a screw hole 60 penetrating in a front and rear direction at a middle part of the longitudinal direction of the protrusion 6.

FIG. 17 illustrates the protrusion 6 located at an upper side of the right wall 43b, and the protrusions 6 are provided at three places of the right wall 43b on which the protrusions 43c, 43c and 43c are disposed in Embodiment 1.

The cover section 42 has the similar configuration as the cover section 43, and the similar protrusions as the protrusion 6 provided on the right wall 43b illustrated in FIG. 17 are provided at three places of the left wall 42b on which the protrusions 42c, 42c and 42c are disposed in Embodiment 1.

As illustrated in FIG. 17, an insertion hole 7 is provided in the upper wall 21b. The insertion hole 7 is a long hole extending in the horizontal direction to have a rectangular cross-section. The insertion hole 7 has a width and length suitable for the protrusion 6 to be inserted thereinto. In an upper side of the bottom plate 21a, a screw through hole 80 is provided at a position corresponding to the middle part of the longitudinal direction of the insertion hole 7 provided in the upper wall 21b.

FIG. 17 illustrates the insertion hole 7 located at the right side of the upper wall 21b, and the insertion holes 7 are provided at four places of the upper wall 21b corresponding to the protrusions 6, 6, 6 and 6 provided on the upper wall 41b. In the upper side of the bottom plate 21a, screw through holes 80, 80, 80 and 80 are provided at positions corresponding to the middle parts of the longitudinal direction of the respective insertion holes 7, 7, 7 and 7 provided in the upper wall 21b.

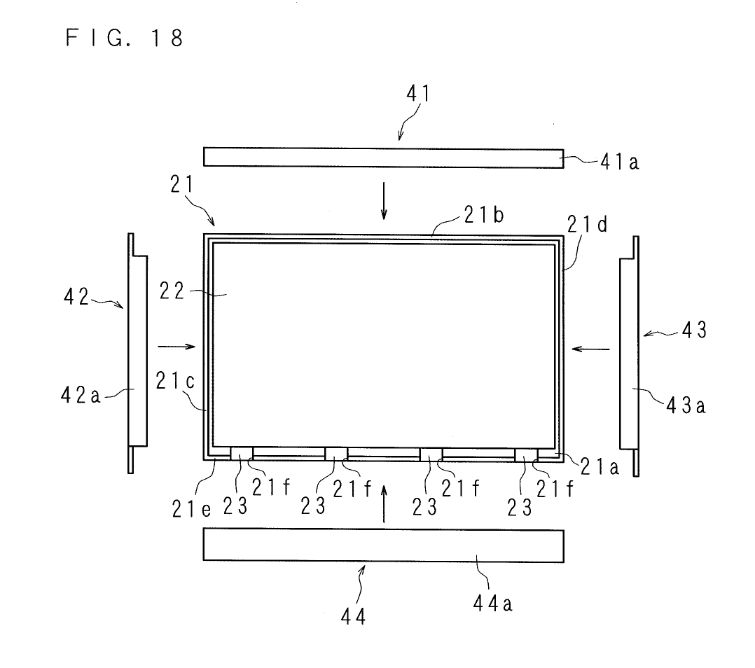

FIG. 18 is a view describing an attaching procedure of the cover sections 41, 42, 43 and 44. When attaching the upper cover section 41 to the upper wall 21b of the backlight chassis 21, the protrusions 6, 6, 6 and 6 of the cover section 41 are respectively inserted into the insertion holes 7, 7, 7 and 7 provided in the upper wall 21b as indicated by an arrow in FIG. 18.

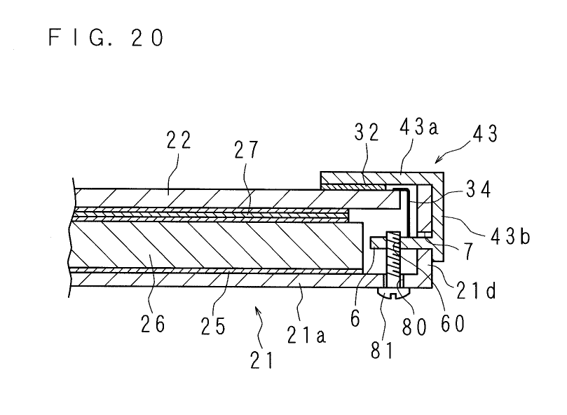

Then, screws 81, 81, 81 and 81 (see FIG. 20), which are described later, are respectively passed through the screw through holes 80, 80, 80 and 80 provided on the upper side of the bottom plate 21a, and are respectively screwed to screw holes 60, 60, 60 and 60 respectively provided in the protrusions 6, 6, 6 and 6 of the cover section 41.

Thereby, the cover section 41 is attached to the upper wall 21b of the backlight chassis 21.

As illustrated in FIG. 17, an insertion hole 7 is also provided in the right wall 21d of the backlight chassis 21. The insertion hole 7 provided in the right wall 21d is a long hole extending in the vertical direction to have a rectangular cross-section.

FIG. 17 illustrates the insertion hole 7 located in the upper side of the right wall 21d, and the insertion holes 7 are provided at three places of the right wall 21b corresponding to the protrusions 6, 6 and 6 provided on the right wall 43b. In the right side of the bottom plate 21a, screw through holes 80, 80, 80 and 80 are provided at positions corresponding to the middle parts of the longitudinal direction of the respective insertion holes 7, 7 and 7 provided in the right wall 43b.

When attaching the right cover section 43 to the right wall 21d of the backlight chassis 21, the protrusions 6, 6 and 6 of the cover section 43 are respectively inserted into the insertion holes 7, 7 and 7 provided in the right wall 21d as indicated by an arrow in FIG. 18.

Then, screws 81, 81 and 81 is respectively passed through the screw through holes 80, 80 and 80 provided at the right side of the bottom plate 21a, and are respectively screwed to screw holes 60, 60 and 60 respectively provided in the protrusions 6, 6 and 6 of the cover section 43.

Thereby, the cover section 43 is attached to the right wall 21d of the backlight chassis 21.

Three insertion holes 7, 7 and 7 are also provided in the left wall 21c of the backlight chassis 21 in the similar manner as the right wall 21d. In the left side of the bottom plate 21a, screw through holes 80, 80 and 80 are provided at left side positions corresponding to the middle parts of the longitudinal direction of the respective insertion holes 7, 7 and 7 provided in the left wall 21c.

The left cover section 42 is attached to the left wall 21c of the backlight chassis 21 in the similar manner as the cover section 43.

The lower cover section 44 is attached to the backlight chassis 21 from the front side so as to cover the lower side of the display panel 22 in the similar manner as the attaching method described in Embodiment 1.

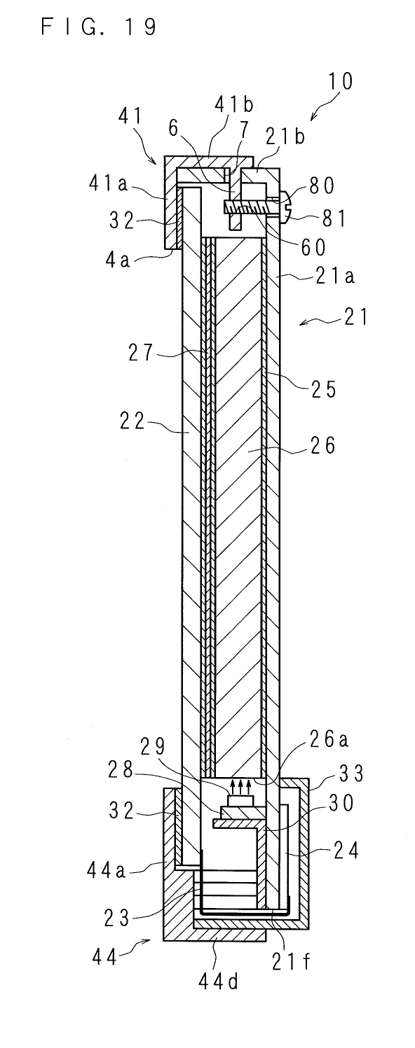

FIG. 19 is a longitudinal cross-sectional view of the display apparatus 10. FIG. 19 illustrates the cross-section of the display apparatus 10 at a position where the protrusion 6 of the cover section 41 is disposed. The lower portion of the front wall 41a of the cover section 41 abuts the display surface of the display panel 22 through the elastic member 32, and covers the upper side of the display surface of the display panel 22.

In the upper wall 21b of the backlight chassis 21, the insertion holes 7, 7, 7 and 7 are provided at the rear side of the display panel 22. The protrusions 6, 6, 6 and 6 of the cover section 41 protrude inward from the upper wall 41b in the display apparatus 10, and are inserted into the insertion holes 7, 7, 7 and 7 provided in the upper wall 21b. The screw through holes 80, 80, 80 and 80 provided at the upper side of the bottom plate 21a respectively face the screw holes 60, 60, 60 and 60 respectively provided in the protrusions 6, 6, 6 and 6 of the cover section 41.

The screws 81, 81, 81 and 81 respectively passed through screw through holes 80, 80, 80 and 80 provided at the upper side of the bottom plate 21a from outside of the backlight chassis 21 are screwed to the screw holes 60, 60, 60 and 60 respectively provided in the protrusions 6, 6, 6 and 6 of the cover section 41. Thus, the cover section 41 is reliably fixed.

FIG. 20 is a transverse cross-sectional view of the right portion of the display apparatus 10. FIG. 20 illustrates the cross-section of the display apparatus 10 at a position where the FPC 34 is not connected to the right side portion of the display panel 22.

The left portion of the front wall 43a of the cover section 43 abuts the display surface of the display panel 22 through the elastic member 32, and covers the right side of the display panel 22.

Each of the insertion holes 7, 7 and 7 provided in the right wall 21d of the backlight chassis 21 is disposed at the rear side of the display panel 22. The protrusions 6, 6 and 6 of the cover section 43 protrude inward from the right wall 43b in the display apparatus 10, and are inserted into the insertion holes 7, 7 and 7 provided in the right wall 21d. The screw through holes 80, 80 and 80 provided on the right side of the bottom plate 21a respectively face the screw holes 60, 60 and 60 respectively provided in the protrusions 6, 6 and 6 of the cover section 43.

The screws 81, 81 and 81 respectively passed through screw through holes 80, 80 and 80 provided at the right side of the bottom plate 21a from outside of the backlight chassis 21 are screwed to the screw holes 60, 60 and 60 respectively provided in the protrusions 6, 6 and 6 of the cover section 43. Thus, the cover section 43 is reliably fixed.

In addition, the transverse cross-section of the left portion of the display apparatus 10 at a position where the FPC 34 is not connected to the left side portion of the display panel 22 is the similar to the transverse cross-section of the right side of the display apparatus 10 illustrated in FIG. 20.

As illustrated in FIGS. 19 and 20, the widths of the upper wall 41b and the right wall 43b are respectively narrower than the widths of the upper wall 21b and the right wall 21d of the backlight chassis 21. Further, the width of the left wall 42b is also narrower than the width of the left wall 21c of the backlight chassis 21, since the transverse cross-section of the left portion of the display apparatus 10 is similar to the transverse cross-section of the right portion of the display apparatus 10. Therefore, the display apparatus 10 seems to be thin, and the display apparatus 10 has a preferable appearance.

As described above, the protrusions 6, 6, . . . , 6 provided on the cover sections 41, 42 and 43 respectively covering the upper, left and right side portions of the display panel 22 are inserted into the insertion holes 7, 7, . . . , 7 provided in the upper wall 21b, the left wall 21c and the right wall 21d of the backlight chassis 21 and then are fixed.

Accordingly, each of the upper cover section 41, the left cover section 42, the right cover section 43 has no groove for fixing the cover sections 41, 42 and 43 to the backlight chassis 21 by screwing, on the front walls 41a, 42a and 43a. Therefore, the width of the front walls 41a, 42a and 43a fringing the display surface of a display panel 22 can be narrow while the appearance can be preferable.

In addition, the backlight chassis 21 which supports the display panel 22, the optical sheet group 27, the light guide plate 26, the reflection sheet 25, or the like, configures a part of the display apparatus 10 as an exterior body, and there is no member covering the entirety of the backlight chassis 21. Therefore, the display apparatus 10, and the television receiver 1 including the display apparatus 10 can be thin and light.

It is noted that the shape of the protrusion 6 is not limited to the rectangular shape. In addition, the screw hole 60 provided in the protrusion 6 is not limited to the middle part of the longitudinal direction of the protrusion 6. When the screw hole 60 is provided at a position other than the middle part of the longitudinal direction of the protrusion 6, the screw through hole 80 is provided at a position of the bottom plate 21a depending on the position of the screw hole 60.

In addition, the number of the insertion holes 7 provided in each of the upper wall 21b, the left wall 21c and the right wall 21d of the backlight chassis 21 may be equal to or larger than the number of the protrusions 6 provided on the cover sections 41, 42 and 43. The number of the protrusions 6 provided on the cover section 41 is not limited to four and may be any appropriate number capable of being disposed within the length range of the upper wall 41b. The number of the protrusions 6 provided on each of the cover sections 42 and 43 is not limited to three and may be any appropriate number capable of being disposed within the length range of the left wall 42b and the right wall 43b.

In addition, there is no need to provide the protrusion 6 in all the cover sections 41, 42 and 43, and the protrusion 6 may be provided on at least one of the cover sections 41, 42 and 43.

In Embodiments 1 and 2, it is not required for the control circuit 24 to be disposed on the outside of the backlight chassis 21. For example, the control circuit 24 may be disposed in the space formed in the stand 13. In such a case, the need for the circuit cover 33 covering the control circuit 24 is eliminated, which allows the display apparatus 10 to be even thinner at the portion where the circuit cover 33 is provided and to thus be even lighter.

In addition, the light source unit is not limited to the light source unit of an edge light type as described in the Embodiments 1 or 2. The light source unit may also be a direct-type light source unit in which LEDs 29, 29, . . . , 29 arranged on the bottom plate 21a directly emit light to the optical sheet group 27.

Further, a cold-cathode tube, e.g., fluorescent tube, may be used in place of the LEDs 29, 29, . . . , 29.

The image displayed on the display apparatus 10 is not limited to the image based on television broadcast. An image concerning the image data obtained from a communication network, for example, the Internet may also be displayed on the display apparatus 10.

1-4. (canceled)

5. A display apparatus, comprising:
an exterior body that surrounds a peripheral surface of a display panel for displaying an image; and
a cover that covers a peripheral edge part of the display panel from an outside of the exterior body,
wherein the cover is configured by a plurality of cover sections, each of which covers a portion of the peripheral edge part of the display panel,
wherein at least one of the plurality of cover sections is provided with an inward protrusion,
wherein a portion of the exterior body is provided with one or more insertion holes of a number equal to or larger than the number of the protrusions, the portion surrounding the peripheral face of the display panel, and
wherein the protrusion is fixed with inserted into the insertion hole.

6. The display apparatus according to claim 5,
wherein each of the plurality of the cover sections has:
a rectangular first cover part that covers a display surface of the display panel; and
a rectangular second cover part that has one side provided continuously at the first cover part and covers the peripheral surface of the display panel,
wherein the protrusion protrudes inward from the second cover part, has a locking claw at a tip end portion thereof, and is fixed by the locking claw locked to an edge part of the insertion hole,
wherein the second cover part of the cover section with the protrusion has both end surfaces respectively abutting the second cover parts of the two cover sections adjacent thereto,
wherein the first cover part of the cover section with the protrusion abuts an end surface of each of the first cover parts of the two cover sections adjacent thereto.

7. The display apparatus according to claim 5,
wherein the insertion hole has:
a first hole that has a rectangular cross-section; and
a second hole that has a smaller rectangular cross-section than the cross-section of the first hole and is formed continuously to one side of the first hole, and
wherein the protrusion has a locking claw at a tip end portion thereof and is fixed by the locking claw locked to an edge part of the second hole.

8. The display apparatus according to claim 5,
wherein the exterior body covers an opposite surface of a display surface of the display panel for displaying an image, and
wherein a portion of the exterior body and the protrusion are fixed to each other by a screw, the portion covering the opposite surface.

9. A television receiver, comprising:
the display apparatus according to claim 5; and
a receiving unit that receives television broadcast,
wherein an image is displayed on the display apparatus based on the television broadcast received by the receiving unit.
